(19) United States
(12) Patent Application Publication
(10) Pub. No.: US 2010/0308468 A1
(43) Pub. Date: Dec. 9, 2010

(54) SEMICONDUCTOR DEVICE AND SEMICONDUCTOR DEVICE FABRICATION METHOD

(76) Inventors: Noriyuki Yoshikawa, Osaka (JP); Toshiyuki Fukuda, Kyoto (JP); Junya Furuyashiki, Kagoshima (JP); Toshimasa Itooka, Kagoshima (JP); Hiroki Utatsu, Kagoshima (JP)

Correspondence Address: MCDERMOTT WILL & EMERY LLP, 600 13TH STREET, NW, WASHINGTON, DC, 20005-3096, US

(21) Appl. No.: 12/867,804

(22) PCT Filed: Mar. 2, 2009
(86) PCT No.: PCT/JP2009/000930

§ 371 Date: Aug. 16, 2010

(30) Foreign Application Priority Data
Mar. 14, 2008 (JP) 2008-065415

(51) Int. Cl. H01L 23/28; H01L 21/78

(52) U.S. Cl. 257/773; 438/113; 257/E23.116; 257/E21.599

(57) ABSTRACT

In a semiconductor device made of a plurality of materials, if the device is fabricated through a step of cutting the bonded plurality of materials, a boundary line of the plurality of materials is exposed on a cutting plane. Internal stress in the cutting remains at this boundary line to allow moisture and corrosive gas to easily enter into the device. In order to reduce the entrance of the moisture, the gas, and the like, the boundary appearing on the cutting plane is covered by a covering layer. At this time, partial cutting exposing the boundary line and not separating semiconductor devices are performed so that the covering layer can be formed with the plurality of semiconductor devices attached to the substrate.

### TECHNICAL FIELD

The present disclosure relates to semiconductor devices and fabrication methods of the semiconductor devices, and more particularly to semiconductor devices in which semiconductor elements mounted on substrates are covered with resin and fabrication methods of the semiconductor devices.

### BACKGROUND ART

In some semiconductor devices, semiconductor elements are arranged on substrates provided with electrodes, and covered with transparent protective layers. This is to protect connecting portions between the semiconductor elements and the substrates, and the semiconductor elements themselves from dust and corrosion due to moisture contained in the air.

A conventionally known problem occurs when a semiconductor element is attached to a metal frame by die attach, and is then molded with resin. More particularly, an oxide layer is formed during the die attach of the semiconductor element. If the oxide layer is left in the molding with the resin, an extremely easily removable oxide layer remains between the resin and the frame, or the resin and the semiconductor element.

The oxide layer absorbs moisture in long-term storage. When the semiconductor device itself is subjected to a heating step such as reflow soldering in the assembly and testing process, this moisture rapidly expands to cause defects such as voids or cracks in the semiconductor device.

As an invention for solving the problem, Patent Document 1 shows an electronic device including a waterproof hardened layer formed on a surface of the semiconductor device. In this invention, a silicon nitride film or a DLC film is formed by plasma CVD on a surface of the electronic device (a DIP) in which an electronic chip is adhered to the lead frame with silver paste and the whole electronic chip is molded with resin, thereby reducing entrance of corrosive gas such as an organic matter and chlorine, and moisture into the chip. PATENT DOCUMENT 1: Japanese Patent Publication No. H02-60150

### SUMMARY OF THE INVENTION

### Technical Problem

Patent Document 1 shows the case where the lead frame and the electrical components are molded as a whole with the resin. However, recent semiconductor devices have been considerably diversified. In most devices, entire packages are not formed with resin only.

For example, in semiconductor devices including electronic components mounted on printing boards, semiconductor elements are mounted on the surfaces of the printing boards, and the semiconductor elements and connecting electrodes are molded with resin.

In a semiconductor device with such a structure, a plurality of semiconductor devices are formed on a single substrate, and separated from the substrate in the last step of the fabrication. At that time, the molding resin and the substrate may be cut at the same time.

Also, in a lead frame semiconductor device, which includes die pads and external terminals in a lead frame, semiconductor elements are mounded on the die pads and molded with resin including the external terminals. The fabrication may include the step of cutting the lead frame and the molding resin at the same time to separate into individual semiconductor devices.

As such, in the step of cutting a plurality of different materials at the same time, stress remains at the cutting portion, since the materials have different hardness and adherence. Corrosive gas and moisture easily leak into the cutting portion, since a boundary line between different materials is exposed at the cutting portion, and since the residual stress exists. That is, there is the problem occurring in a semiconductor device made of a plurality of materials and subjected to a step of cutting the materials at the same time.

### Solution to the Problem

In order to solve the above-described problem, a semiconductor device of the present invention includes a base including at least one external terminal and an element mounting portion, a semiconductor element mounted on the element mounting portion, a connecting portion electrically connecting the external terminal and the semiconductor element; and first resin covering the semiconductor element and the connecting portion. At least part of a boundary line being an end of a boundary plane between the base and the first resin is covered with a covering layer. The part exists on at least one cutting plane along which the base and the first resin are cut.

A fabrication method of a first semiconductor device of the present invention includes mounting a semiconductor element on a substrate body including at least one through hole and provided with an external terminal in the through hole, electrically connecting the semiconductor element to a part of the external terminal; encapsulating the semiconductor element and the part of the external terminal with resin; newly exposing a boundary line being an end of a boundary plane between the substrate body and the resin by cutting the resin and a part of the substrate body in a thickness direction; forming a covering layer covering the boundary line; and cutting a residual which has not been cut in the exposing and remains in the thickness direction of the substrate body to separate the substrate body into individual substrates.

A fabrication method of a second semiconductor device of the present invention includes mounting a semiconductor element on a die pad of a base which is a lead frame including the die pad and an external terminal, electrically connecting the semiconductor element to the external terminal, encapsulating the semiconductor element and the external terminal with first resin; exposing a boundary line being an end of a boundary plane between the external terminal and the first resin by cutting the first resin and a part of the external terminal in a thickness direction, forming a covering layer covering the boundary line; and cutting a residual which has not been cut in the exposing and remains in the thickness direction of the external terminal.

### Advantages of the Invention

The semiconductor device of the present invention is made of a plurality of materials. On a cutting plane including a boundary line between the different materials, the boundary line is protected by a covering layer to reduce entrance of moisture and corrosive gas from the boundary line on the cutting plane in which stress remains. In short, a semiconductor device with high resistance to environment can be provided.

### BRIEF DESCRIPTION OF THE DRAWINGS

FIG. 1 is a schematic view illustrating the structure of a semiconductor device according to an embodiment. FIG. 1(a) is a cross-sectional view taken along the line A-A′. FIG. 1(b) is a plan view. FIG. 1(c) is a cross-sectional view taken along the line B-B′.

FIG. 2 is an enlarged view of an end portion of the semiconductor device according to the embodiment.

FIG. 3 illustrates steps of fabricating the semiconductor device according to the embodiment.

FIG. 4 illustrates an example connection of the semiconductor device according to the embodiment.

FIG. 5 illustrates the steps of partial cutting, formation of a covering layer, and cutting.

FIG. 6 illustrates the steps of partial cutting using a blade with a side taper, formation of a covering layer, and cutting.

FIG. 7 illustrates a fabrication method of a lead frame semiconductor device.

FIG. 8 illustrates the step of partial cutting of a lead frame type.

FIG. 9 illustrates the step of partial cutting where a resin layer is provided in addition to an external terminal.

FIG. 10 illustrates the structure of a lead frame semiconductor device.

### DESCRIPTION OF REFERENCE CHARACTERS

1 Semiconductor Device

3 Substrate

5 Through Hole

6 Mounting Surface

8 Element Mounting Portion

10 Semiconductor Element

11 Projecting Bump

12 Operation Area

18, 18′, 18″ External Terminals

20 Bonding Wire

24 First Resin

26 Cutting Plane

29, 29′ Boundary Lines

30 Covering Layer

33 Substrate Body

39 Partial Cut

44 Die Pad

50 Second Resin

51 Second Boundary Line

### DESCRIPTION OF EMBODIMENTS

### First Embodiment

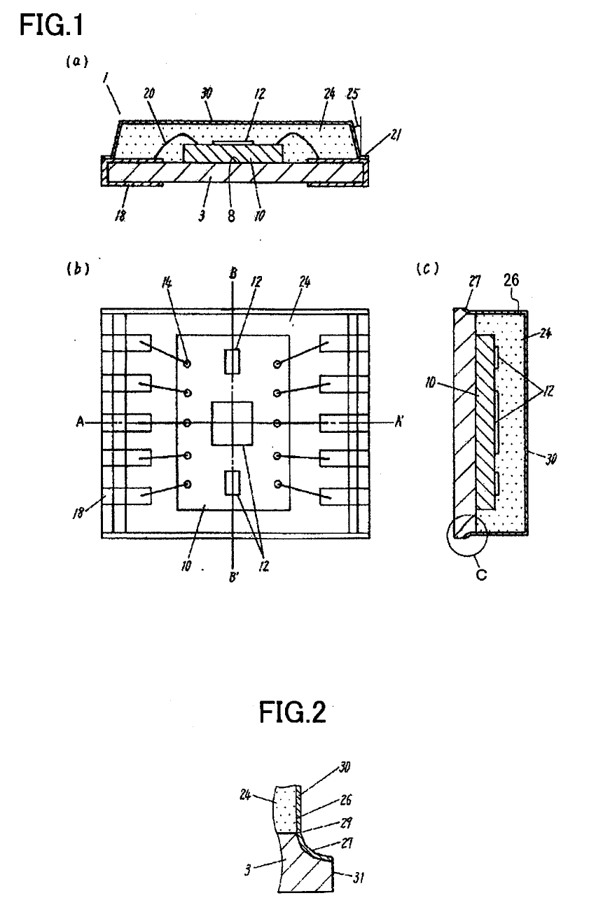

FIG. 1 is a schematic view illustrating the structure of a semiconductor device 1 according to a first embodiment. FIG. 1(b) is a plan view. FIG. 1(a) is a cross-sectional view taken along the line A-A′ in FIG. 1(b). FIG. 1(c) is a cross-sectional view taken along the line B-B′ in FIG. 1(b). Note that in FIG. 1(b), translucent first resin 24 being sealing resin and a covering layer 30 are transparent for convenience of explanation to show the inner structure.

In the semiconductor device 1, a semiconductor element 10 is mounted on an element mounting portion 8 in a substrate (base) 3 provided with external terminals 18 being electrodes. The semiconductor element 10 of this embodiment is an optical semiconductor element in which light emitting or light receiving regions (the combination of the light emitting region and the light receiving region are hereinafter referred to as an “operation area”) 12 and the bonding pads 14 for wire bonding are formed on a semiconductor substrate such as a silicon substrate.

A plurality of operation areas 12 may be formed on a single semiconductor element 10. FIG. 1 illustrates an example where three operation areas 12, 12, and 12 are formed on a single semiconductor element 10. Five bonding pads 14 are formed on each of the left and right sides of the semiconductor element 10 being a rectangle plane.

The material for the substrate 3 is not limited but may be preferably epoxy such as glass epoxy, phenol, Teflon (registered trademark), polyethylene, and the like. A plurality of external terminals 18 are formed on both sides of the substrate 3. The external terminals 18 may be formed on the front surface of the substrate 3 and may be formed on the front and back surfaces with through holes interposed therebetween. FIG. 1 illustrates an example where the external terminals 18 are formed from the front surface to the back surface through the side surface of the substrate 3.

The external terminals 18 of the substrate 3 and the bonding pads 14 of the semiconductor element 10 are connected together by bonding wires (connecting portions) 20.

The semiconductor element 10 and the bonding wires 20 are sealed with the first resin 24. As such, by encapsulating with the resin, disconnection of the bonding wires 20 and damages of the semiconductor element 10 can be reduced.

The first resin 24 does not cover the entire upper surface of the substrate 3 on a side surface of the substrate 3 provided with the external terminals 18 (FIG. 1(a)). An unsealed portion 21 slightly exists at the end of the upper surface of the substrate 3. This is because width for pressing a mold for encapsulating is needed. Also, the first resin 24 has a taper angle 25 for removing the mold.

On the other hand, a side surface orthogonal to the side surface provided with the external terminals 18 is a substantially vertical cutting plane 26 (FIG. 1(c)), and has a small step 27. Two sides of the substrate 3 not provided with the external terminals 18 are the cutting planes 26. This small step 27 is generated in the step of forming the covering layer 30 on a boundary line between the first resin 24 and the substrate 3 in the below-described fabrication method of the semiconductor device according to this embodiment.

The covering layer 30 is formed at the end of a boundary plane between the first resin 24 and the substrate 3 (the boundary line exposed outward) and on the surface of the first resin 24 to reduce the entrance of moisture, corrosive gas, and the like. As the covering layer 30, a silicon nitride film, a silicon dioxide film, a diamond-like carbon (DLC) film, a fiber reinforced plastic (FRP) film, and the like can be preferably used.

FIG. 2 is an enlarged view of the end C of FIG. 1(c). Translucent first resin 24 exists on the substrate 3. A boundary line 29, which is an end of the boundary plane between the first resin 24 and the substrate 3, is exposed on a cutting plane 26. (Note that the boundary line 29 is already covered with the covering layer 30. The covering layer 30 covers the cutting plane 26 to cover the boundary line 29. This covering layer 30 covers at least the boundary line 29, preferably covers the entire cutting plane 26, and more preferably covers the first resin 24 and the cutting plane 26 as a whole. This is to reduce the entrance of moisture and the like. At a part of the small step 27, a portion 31 not provided with the covering layer 30 exists in the following fabrication method.

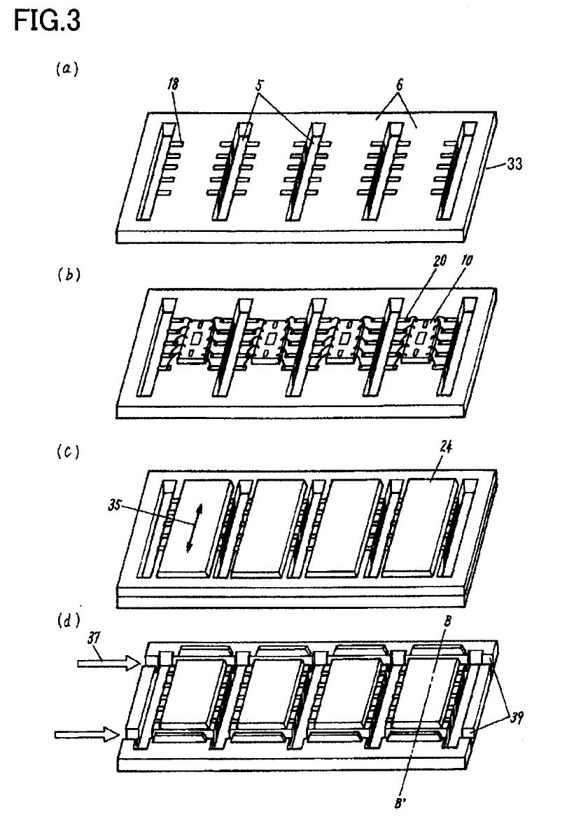

Next, the fabrication method of the semiconductor device of this embodiment will be described hereinafter with reference to FIG. 3.

In a substrate body 33, which will be a plurality of substrates 3 later, the semiconductor elements 10 are mounted on a mounting surface 6, a plurality of through holes 5 extending like slits are formed, and the through holes 5 extend parallel to each other. A plurality of semiconductor devices are separated from the substrate body 33. The external terminals 18 are formed in advance on wall surfaces of the through holes 5 (FIG. 3(a)).

Then, the semiconductor elements 10 are bonded to the mounting surface 6 with an adhesive. The semiconductor elements 10 may be of a light receiving type or a light emitting type. Thereafter, the semiconductor elements 10 are wire bonded to the external terminals 18 of the substrate body 33 (FIG. 3(b)).

Ball bonding, wedge bonding, and the like can be used as the wire bonding.

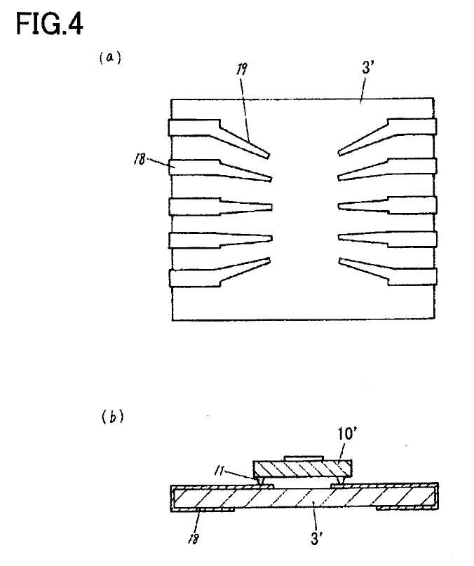

Note that the semiconductor elements 10 and the external terminals 18 may be connected together not only by bonding wires but also by projecting bumps. FIG. 4 illustrates example projecting bumps 11. Connecting terminals 19 extending from the external terminals 18 are arranged on the substrate 3′ (FIG. 4(a)). On the other hand, the conical projecting bumps 11 are formed on the back surface of the semiconductor element 10′. The projecting bumps 11 are formed on the semiconductor element 10′ instead of bonding pads. Contact between the projecting bumps 11 and the connecting terminals 19 ensures an electrical connection between the semiconductor element 10′ and the external terminals 18 (FIG. 4 (b)).

Referring back to FIG. 3, after connecting the external terminals 18 and the semiconductor elements 10 together by the bonding wires 20, an upper portion of the substrate body 33 is molded with the first resin 24. A mold is formed with a small space left on the side provided with the external terminals 18 of the substrate body 33 (i.e., the side provided with the through holes 5) (FIG. 3(c)).

Note that the first resin 24 may be formed long to exceed the length of the semiconductor elements 10 in a direction 35 parallel to the side provided with the external terminals 18. This is because the length in this direction can be uniform through a cutting step later.

Then, the first resin 24 and a part of the substrate body 33 in a thickness direction (i.e., the side being in contact with the first resin 24) are cut in a single step from a direction 37 orthogonal to the side provided with the external terminals 18 (FIG. 3 (d)). The cut portion is apart from the side orthogonal to the side arranged with bonding pads of the semiconductor elements 10 with a predetermined distance. The portion is cut parallel to the orthogonal side. This cutting is called partial cutting 39. The partial cutting 39 cuts the substrate body 33 together with the first resin 24 so that the substrate body 33 slightly remains in the thickness direction, thereby forming cutting planes of the first resin 24 and the substrate 3. This is because the cutting is performed in single processing with the cutting planes of the first resin 24 and the substrate 3 exposed at these portions when the substrate body 33 is not yet separated.

The first resin 24 is formed slightly large in the direction 35 parallel to side provided with slit-like through holes 5 provided with the external terminals 18 to sufficiently seal the semiconductor elements 10 and the external terminals 18. This is because, the flexibility for determining the size of the semiconductor devices increases with an increase in the size of the first resin 24. For example, even if the semiconductor devices have the same function, various size of the semiconductor devices are required depending on the places where the semiconductor device are used. That is, small-sized semiconductor devices are not necessarily required. Thus, in order to control the length in that direction, the first resin 24 is cut together with the substrate 3 to be a predetermined size.

Then, a boundary line between the first resin 24 and the substrate 3 appears on the cutting plane. Stress generated during the cutting remains near the boundary line having appeared on the cutting plane so that moisture and the like can enter the inside of the semiconductor device from the boundary line. Thus, in this embodiment, the boundary line is protected by with the covering layer 30. If the individual semiconductor devices are separated at this time, the following steps are difficult to perform. Therefore, the semiconductor devices are connected as the substrate body 33 with the boundary line on the cutting plane exposed. After the partial cutting, the covering layer 30 is formed from the upper portion of the substrate body 33.

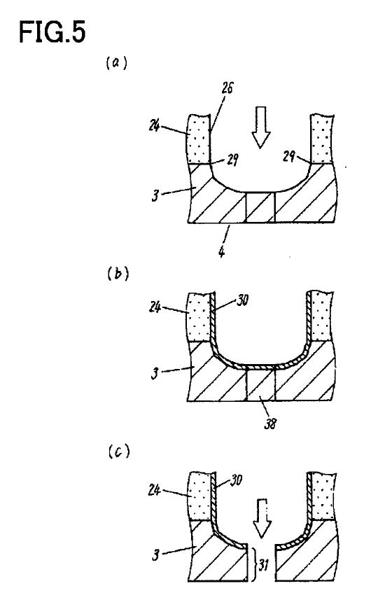

FIG. 5 illustrates an enlarged view of the partial cut 39. FIG. 5 is an enlarged view of a partial cross-section taken along the line B-B′ in FIG. 3(d). The first resin 24 is on the substrate 3. A groove is formed in the first resin 24 and the substrate 3 by dicing (FIG. 5(a)). This is partial cutting. A blade to be used preferably has a U-shaped cross-section and a large thickness. The partial cutting creates the cutting plane 26 so that a boundary line 29 between the first resin 24 and the substrate 3 appears. When the semiconductor device is left in this state, moisture and corrosive gas enter the inside of the semiconductor device from this exposed boundary line 29, and are stored at the interface between the first resin 24 and the substrate 3. Note that a reference numeral 4 denotes the bottom surface of the substrate 3.

Next, the covering layer 30 is formed on the cutting plane 26 (FIG. 5(b)). The method of forming the covering layer 30 is not limited, but vacuum processing is preferable to form the covering layer 30 as a thin film. Vapor deposition, sputtering, plasma CVD and the like are preferably used as long as it is performed under vacuum. Since the cutting plane 26 is almost vertical to the upper surface of the substrate 3, plasma DVD with a short mean-free-path, large wraparound of flying particles and excellent step coverage is preferably used. Clearly, methods such as spraying may be used.

The covering layer 30 preferably has transmittance of 85% or more, and more preferably 90% or more. Also, the refractive index is preferably 1.9 or less, and more preferably 1.8 or less. If the transmittance is low, and the refractive index is high, light emission or light reception cannot be performed well and satisfactory performance of the semiconductor device cannot be obtained.

In this embodiment, when forming the covering layer 30, a film material is irradiated from the upper portion of the semiconductor device 1. Thus, the covering layer 30 is formed not only over the boundary line, but also over the surface of the first resin 24, and all over a boundary line between the first resin 24 and the substrate 3 at the side of the external terminals 18. This is because moisture and corrosive gas may enter from these portions.

Then, dicing is performed again to cut the residual of the substrate body 33 (FIG. 5(c)). At this time, a blade, which has a smaller thickness than the blade used for dicing in

FIG. 5(a), is used for cutting a bottom portion of the groove of the partial cutting. This not to damage the covering layer 30 formed on the cutting plane of the substrate 3 and the first resin 24. Through this step, the cutting plane is necessarily provided with the portion 31 without the covering layer 30 and exposing the substrate 3 itself. Furthermore, the substrate 3 projects more outward than the first resin 24 on the cutting plane. In this step, the semiconductor devices are separated from the substrate body 33, thereby ending the manufacturing process.

Note that a U-shaped dicing blade is used for the partial cutting. Thus, the cutting planes of the substrate 3 and the first resin 24 are substantially vertical to the upper surface of the substrate. While the covering layer 30 can be formed on a vertical cutting plane by plasma CVD, the film formation rate can be improved if the cutting plane faces more upward. Thus, a blade with a side taper may be used for the partial cutting.

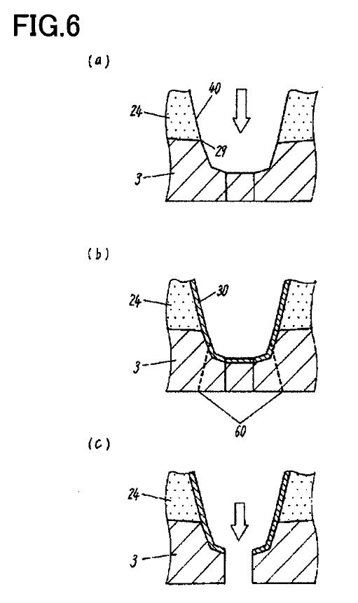

FIG. 6 illustrates the shape of the cutting plane where partial cutting is performed with a blade having a side taper. When the partial cutting is performed with the blade having the side taper, a slope 40 is formed on the cutting plane. Specifically, the opening of the groove formed by partial cutting gradually expands toward the upper portion. Due to the slope, the boundary line 29 faces slightly upward to increase the film formation rate in the formation of the covering layer from above.

After forming the covering layer 30, the residual of the substrate 3 is cut from the direction of the partial cutting, but the residual may be cut from the back side of the substrate 3. For example, FIG. 6(b) illustrates a cutting plane line 60 when the cutting is performed from the back surface of the substrate 3. When the cutting is performed along the cutting plane line, the small step 27 is not formed. However, the covering layer 30 is formed over the boundary line between the first resin 24 and the substrate 3, thereby achieving the objective of the present invention (FIG. 6(c)).

### Second Embodiment

A semiconductor device according to a second embodiment is a so-called lead frame semiconductor device. A description is as follows.

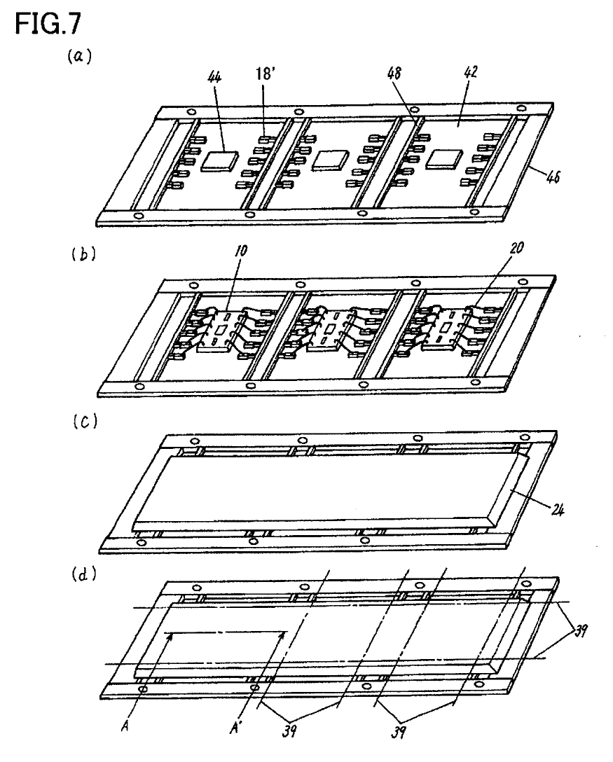

The outline of a fabrication method of the lead frame semiconductor device will be described with reference to FIG. 7. A lead frame 46 is arranged, which includes a frame, die pads 44, and external terminals 18′ on a tape 42 having a relatively high melting point (FIG. 7(a)). As a specific material for the tape 42, polyethylene terephthalate (PET), polyethylene naphthalate (PEN), polyimide, and the like are preferably used. A plurality of external terminals 18′ are connected together to a runner 48. These terminals may be temporarily bonded with an adhesive applied onto the tape 42. The die pads 44 are element mounting portions on which semiconductor elements 10 are mounted. Furthermore, the die pads 44 are not integrated with the external terminals 18′. However, since the die pads 44 and the external terminals 18′ are integrated after being molded with resin in the assembly and testing process, the lead frame 46 including the die pads 44 and the external terminals 18′ can be regarded as a base. After the molding, the tape 42 may be removed. This is because the external terminals 18′ and the semiconductor elements 10 are fixed by molding.

The die pads 44 and the external terminals 18′ are preferably made of conductive metal. Specifically, metal such as metal, nickel, copper, zinc, aluminum, zinc, aluminum, silver, and gold, and alloys thereof are preferable.

Next, the semiconductor elements 10 are bonded to the die pads 44 (FIG. 7(b)). A die attach adhesive may be used for the bonding. The die attach adhesive is conductive. Then, the semiconductor elements 10 are connected to the external terminals 18′ by the bonding wires 20.

Thereafter, the entire device is sealed with translucent first resin 24 (FIG. 7(c)). The first resin 24, which can be used here, is preferably acrylic resin in view of translucency and hardness. The first resin 24 seals the device to completely cover the semiconductor elements 10, the bonding wires 20, and the external terminals 18′. The method of applying the sealing resin is not limited. However, printing is preferably used considering that the resin can be uniformly applied with a predetermined thickness in a predetermined position.

Note that transmittance of the covering layer 30 is preferably 85% or more, and more preferably 90% or more. The refractive index is preferably 1.9 or less, and more preferably 1.8 or less. If the covering layer 30 has low transmittance and a high refractive index, light is not emitted or received well. It is thus possible that the semiconductor device cannot provide satisfactory performance.

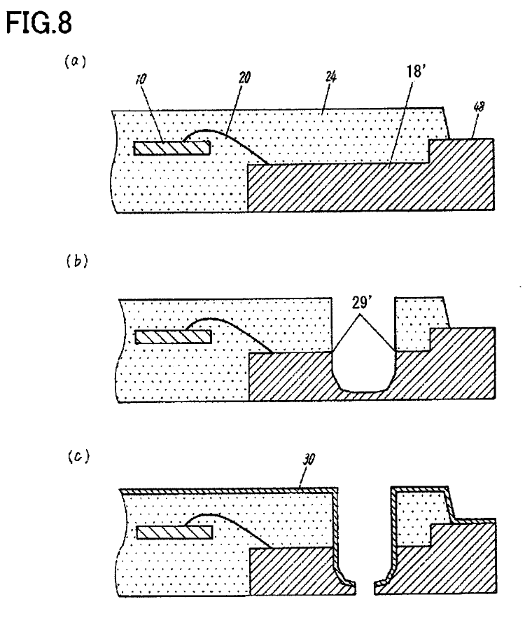

Then, partial cutting 39 is performed as a stage prior to separating individual semiconductor devices in both of the length and width directions of the tape 42 (FIG. 7(d)). This exposes both of the side at which the external terminals 18′ are exposed, and a side orthogonal to the side except for the lowermost portions. FIG. 8(b) illustrates the enlarged view.

Next, with reference to the schematic cross-section of FIG. 8, steps of before and after the partial cutting, and the full cutting process will be described. FIG. 8(a) illustrates the state before the partial cutting. A semiconductor element 10 is connected to an external terminal 18′ by a bonding wire 20. The semiconductor element 10 is mounted on a die pad, which is not shown. The external terminal 18′ is provided in connection with the runner 48. This is because a plurality of external terminals 18′ can be arranged together. The semiconductor element 10 is connected by the bonding wire 20, and then sealed with first resin 24.

Then, the partial cutting is performed with a U-shaped blade (FIG. 8(b)). This exposes a boundary line 29′, which is an end of a boundary plane between the first resin 24 and the external terminal 18′, on the cutting plane. Since a part of the external terminal 18′ is connected to the runner 48, a plurality of semiconductor devices formed on a single tape 42 are not separated and can be handled as an aggregation. As described in the first embodiment, moisture and corrosive gas tends to enter the device, since internal stress remains near the boundary line 29′.

Thereafter, the boundary line 29′ between the first resin 24 and the external terminals 18′ is covered with the covering layer 30, thereby preventing the entrance of moisture and gas. After that, the resin 24 is cut (FIG. 8(c)).

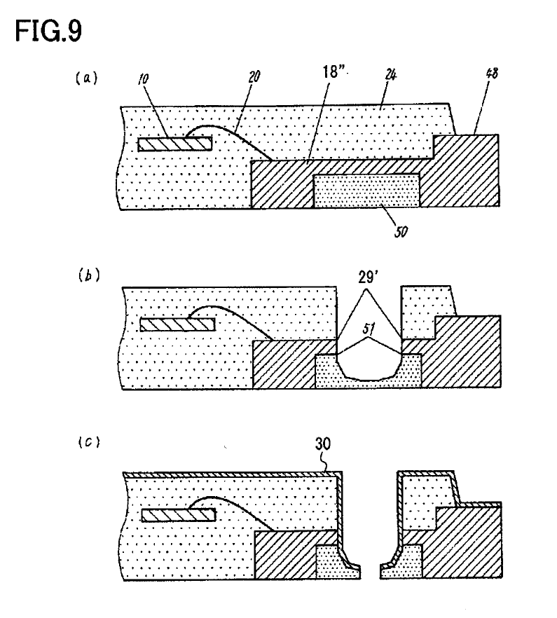

FIG. 9 illustrates the case where an external terminal 18″ is supported by second resin 50 provided at a part under the external terminal 18″ (FIG. 9(a)), In this case, the external terminal 18″ is completely cut in the thickness direction in partial cutting. Specifically, a metal layer of the external terminal 18″ is completely cut in the thickness direction, a second resin layer under the metal layer is partially cut in the thickness direction. Then, two lines of a boundary line 29′ between the first resin 24 and the external terminal 18″, and a second boundary line 51 between the external terminals 18″ and the second resin 50 are exposed on the cutting plane (FIG. 9(b)). These two boundary lines 29′ and 51 are covered together by the covering layer 30 (FIG. 9(c)). As such, it becomes more difficult for moisture and gas to enter the device, since the second boundary line 51 between the external terminals 18″ and the second resin 50 exists until the moisture and gas reaches the boundary line 29′ between the external terminals 18″ and the first resin 24 used as sealing resin.

Since the second resin 50 can be provided when forming the metal external terminals 18″ connected to the runner 48, the type of resin is not limited and may be thermoplastic or thermoset resin. However, resin having high hardness after curing is suited, since the resin is subjected to the above-described cutting process when being incorporated into the semiconductor device.

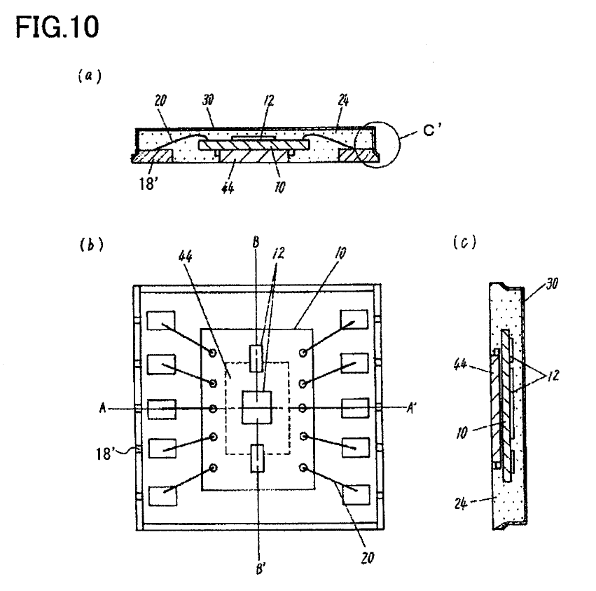

FIG. 10 is a plan view and a cross-sectional view of a lead frame semiconductor device. FIG. 10(b) is a plan view. A semiconductor element 10 is mounted on a die pad (element mounting portion) 44, and external terminals 18′ are arranged on the both sides of the semiconductor element 10. The semiconductor element 10 may include a plurality of operation areas 12. The operation areas 12 may be for light emission or light reception. The semiconductor element 10 is connected to the external terminals 18′ by the bonding wires 20. FIG. 10(a) illustrates a cross-section taken along the line A-A′ in this plan view. The covering layer 30 covers the surface of the first resin 24 and side surfaces. FIG. 10(a) illustrates the cross-section of an external terminal 18′. FIG. 8 is an enlarged view of the part C′.

FIG. 10(c) illustrates a cross-section taken along the line B-B′ in the plan view of FIG. 10(b). In this figure, the both ends are covered with the covering layer 30 after partial cutting.

This part is formed by the first resin 24 only, and the cross-section is of the first resin 24 only. Therefore, the covering layer 30 may not be formed on this plane.

### INDUSTRIAL APPLICABILITY

The present invention is useful when fabricating a semiconductor device made of a plurality of materials through a cutting step.

1. A semiconductor device comprising:
a base including at least one external terminal and an element mounting portion;
a semiconductor element mounted on the element mounting portion;
a connecting portion electrically connecting the external terminal and the semiconductor element; and
first resin covering the semiconductor element and the connecting portion, wherein
at least part of a boundary line being an end of a boundary plane between the base and the first resin is covered with a covering layer, the part existing on at least one cutting plane along which the base and the first resin are cut.

2. The semiconductor device of claim 1, wherein
a part of the cutting plane formed by the base includes a part projecting more outward than a part of the cutting plane formed by the first resin exists.

3. The semiconductor device of claim 1 or 2, wherein
the base is a substrate including the element mounting portion and the external terminal.

4. The semiconductor device of claim 1 or 2, wherein
the first resin covers a part of a surface of the substrate, on which the semiconductor element is mounted.

5. The semiconductor device of claims 1 or 2, wherein
the connecting portion is a metal thin wire or a projecting bump.

6. The semiconductor device of claims 1 or 2, wherein
the substrate is a rectangle plate,
multiple ones of the at least one external terminal are arranged on two facing sides of the substrate, and
multiple ones of the at least one cutting plane are two facing sides of the substrate, which are not provided with the external terminals.

7. The semiconductor device of claims 1 or 2, wherein
the cutting plane includes a curbed surface.

8. The semiconductor device of claims 1 or 2, wherein
the covering layer completely covers the boundary line between the first resin and the substrate.

9. The semiconductor device of claim 1 or 2, wherein
the element mounting portion is a die pad, and
the boundary line on the cutting plane is a boundary line between the external terminal and the first resin.

10. The semiconductor device of claim 9, wherein
the external terminal includes a portion supported by second resin, and
the cutting plane further includes a second resin boundary line being an end of a boundary plane between the external terminal and the second resin.

11. The semiconductor device of any one of claims 1 or 2, wherein
the first resin is translucent, and
the covering layer has a transmittance of 85% or more.

12. The semiconductor device of any one of claims 1 or 2, wherein
the covering layer has a refractive index of 1.8 or less.

13. A fabrication method of a semiconductor device comprising:
mounting a semiconductor element on a substrate body including at least one through hole and provided with an external terminal in the through hole;
electrically connecting the semiconductor element to a part of the external terminal;
encapsulating the semiconductor element and the part of the external terminal with resin;
newly exposing a boundary line being an end of a boundary plane between the substrate body and the resin by cutting the resin and a part of the substrate body in a thickness direction;
forming a covering layer covering the boundary line; and
cutting a residual which has not been cut in the exposing and remains in the thickness direction of the substrate body to separate the substrate body into individual substrates.

14. The method of claim 13, wherein
at least one through hole is a slit, and is a plurality of through holes formed parallel to each other in the substrate body, and
the boundary line is substantially vertical to a direction in which the slit extends.

15. The method of claim 13, wherein
the exposing is cutting with a blade having a U-shaped cross-section.

16. The method of claim 13, wherein
the exposing is cutting with a blade having a taper on a side surface.

17. A fabrication method of a semiconductor device comprising:
mounting a semiconductor element on a die pad of a base which is a lead frame including the die pad and an external terminal;
electrically connecting the semiconductor element to the external terminal;
encapsulating the semiconductor element and the external terminal with first resin;
exposing a boundary line being an end of a boundary plane between the external terminal and the first resin by cutting the first resin and a part of the external terminal in a thickness direction;
forming a covering layer covering the boundary line; and
cutting a residual which has not been cut in the exposing and remains in the thickness direction of the external terminal.

18. The method of claim 17, wherein
the external terminal includes a part having a double layer structure of a metal layer and a second resin layer of second resin, and
the exposuring is exposure of a boundary line being an end of a boundary plane between the metal layer and the first resin, and a second resin boundary line being an end of a boundary plane between the metal layer and the second resin layer by cutting the first resin, the metal layer, and a part of the second resin layer.
